(19) United States
(12) Patent Application Publication
(10) Pub. No.: US 2024/0426923 A1
(43) Pub. Date: Dec. 26, 2024

(54) BATTERY MANAGEMENT SYSTEM FOR DETECTING ABNORMAL BATTERY CONDITIONS

(71) Applicant: Sloan Valve Compay, Franklin Park, IL (US)

(72) Inventors: Kay Herbert, Winthrop, MA (US); Hemant Patel, Windham, NH (US); Sheng Deng, Lexington, MA (US); Qiaohong Chen, Lexington, MA (US); Xu Wang, Lake Forest, IL (US)

(21) Appl. No.: 18/748,215

(22) Filed: Jun. 20, 2024

Related U.S. Application Data
(60) Provisional application No. 63/521,899, filed on Jun. 20, 2023.

(51) Int. Cl. G01R 31/3835; G01R 31/36; G01R 31/371; G01R 31/392

(52) U.S. Cl. CPC G01R 31/3835; G01R 31/3646; G01R 31/371; G01R 31/392

(57) ABSTRACT

The present disclosure describes a system that monitors an alkaline battery pack to detect low voltage batteries before the low voltage batteries can leak. Battery packs may comprise an even number of batteries, operating in series. The system monitors a voltage over each pair of batteries in a battery pack. For example, a first voltage (V₁) may be measured between a first battery and a second battery. The first voltage may be measured between ground and the middle of the battery pack. The second voltage (V₂) may be measured between a third battery and a fourth battery (i.e., between the middle of the pack and the terminal). The system then estimates the lowest battery voltage (Vₜₑₛₜ) by subtracting the higher voltage divided by two from the lower voltage. The resultant voltage (Vₜₑₛₜ) is then compared to a threshold voltage (e.g., between 0.85-1.2 volts). If the resultant voltage (Vₜₑₛₜ) is greater than the threshold voltage, then the device is allowed to continue operating. However, if the resultant voltage (Vₜₑₛₜ) is lower than the threshold voltage, the system detects an abnormal battery and stops operation of the device to prevent the battery from leaking and/or corroding the device.

### REFERENCE TO RELATED APPLICATIONS

This application claims priority to U.S. Provisional Application No. 63/521,899, filed on Jun. 20, 2023 and entitled “Battery Management System for Detecting Abnormal Battery Conditions,” the entirety of which is hereby incorporated by reference for all purposes.

### FIELD OF THE INVENTION

Aspects of the disclosure generally relate to battery management and more specifically to avoid battery leaks and/or to minimize potential for batteries that may be predisposed to leaking.

### BACKGROUND OF THE INVENTION

Battery leakage occurs in alkaline batteries when hydrogen gas inside the battery increases in pressure to a point where the pressure from the hydrogen gas forces electrolyte liquid to be released through a vent or seal. Typically, battery leakage can occur when the battery voltage drops below 0.8 volts, and battery manufacturers advise that alkaline batteries should not be operated below 0.8 volts to prevent potential battery leakage. If battery leakage occurs, the chemical electrolyte may cause corrosion and/or shorten the life of the powered device.

Existing solutions provide a separate battery pack housing that contains any battery leakage and/or limits battery leakage damage to the separate battery pack housing. However, these separate battery pack housings are expensive because the case must be manufactured and contain power connections. Moreover, some devices that would benefit from having a separate battery pack housing may not have the room for such a separate housing.

Other solutions continuously monitor the combined voltage of battery packs. While this is useful in detecting when batteries are at the end of their life, this methodology is not helpful in detecting a single rogue, discharged, and/or defective battery in a battery pack. Conversely, monitoring each battery individually is simply impractical. In addition, alkaline batteries are mass produced in a way that quality is not assured for a percentage of batteries. Accordingly, there is a need in the art to monitor battery consumption and detect rogue, discharged, and/or defective batteries in battery packs.

### SUMMARY OF THE INVENTION

The following presents a simplified summary of various features described herein. This summary is not an extensive overview, and is not intended to identify key or critical elements or to delineate the scope of the claims. The following summary merely presents some concepts in a simplified form as an introductory prelude to the more detailed description provided below. Corresponding apparatus, systems, and computer-readable media are also within the scope of the disclosure.

According to aspects of the present disclosure, methods, devices, systems, and/or instructions stored on non-transitory computer-readable media for monitoring battery packs and detecting abnormal battery conditions (e.g., conditions that can lead to battery leakage) are described herein. The battery packs may comprise an even number of batteries, operating in series. Battery packs may comprise four (4) batteries, and the system described herein may monitor two voltages: a first voltage between ground and a full load of the battery pack (e.g., 4 batteries) and a second voltage between the middle of the pack and a ground (e.g., terminal). The system then estimates the lowest battery voltage by subtracting the higher voltage divided by two from the lower voltage. The resultant voltage may be compared to a threshold voltage (e.g., between 0.85-1.2 volts). If the resultant voltage is greater than the threshold voltage, then the device may be allowed to continue operating. However, if the resultant voltage is lower than the threshold voltage, the system may determine an abnormal battery condition, such as a low (e.g., end of life) battery, a defective battery, and/or a leaking battery. The abnormal battery condition may cause an indicator (e.g., indication) to be presented to a user indicating the abnormal (e.g., low) battery condition. Additionally or alternatively, the system may stop operation of the device to prevent the battery from leaking and/or corroding by extending the time it will take for the battery to discharge to the critical voltage (typically 0.8 V) where it can leak, reducing the discharge current the battery experiences. The detection techniques described herein may be applied at a factory, for example, as part of a new battery installation screening process. Any battery that fails thresholds described herein may be treated as a defective battery.

Other aspects, objectives and advantages of the invention will become more apparent from the following detailed description when taken in conjunction with the accompanying drawings.

### BRIEF DESCRIPTION OF DRAWINGS

The present disclosure is described by way of example and not limited in the accompanying figures in which like reference numerals indicate similar elements and in which:

FIGS. 1A & 1B show an example of a system implementing a battery monitoring system according to one or more aspects of the disclosure;

FIG. 2 shows an example of a battery monitoring system according to one or more aspects of the disclosure;

FIG. 3A-3D show various perspectives of an exploded view of a battery pack including the battery monitoring system discussed in according with one or more aspects described herein; and

FIG. 4 shows an example of a process for detecting an abnormal battery in accordance with one or more aspects of the disclosure.

### DETAILED DESCRIPTION OF THE INVENTION

In the following description, reference is made to the accompanying drawings, which form a part hereof, and in which are shown various examples of features of the disclosure and/or of how the disclosure may be practiced. It is to be understood that other features may be utilized and structural and functional modifications may be made without departing from the scope of the present disclosure. The disclosure may be practiced or carried out in various ways. In addition, it is to be understood that the phraseology and terminology used herein are for the purpose of description and should not be regarded as limiting. Rather, the phrases and terms used herein are to be given their broadest interpretation and meaning.

By way of introduction, features discussed herein may relate to methods, devices, systems, and/or instructions stored on non-transitory computer-readable media for detecting leaking batteries or batteries that are at a voltage state where they may potentially leak in the near future. Specifically, the methods, devices, systems, and/or instructions stored on non-transitory computer-readable media described herein monitor alkaline battery packs to detect abnormal battery conditions. The battery packs may comprise an even number of batteries, operating in series. Preferably, the battery packs comprise four (4) batteries; however, the techniques described herein may be expanded to battery packs containing more than four batteries. In operation, the system monitors a voltage over each pair of batteries in a battery pack. That is, a first voltage (V₁) may be measured between a first battery and a second battery (e.g., the voltage between ground and the middle of the battery four-pack). The second voltage (V₂) may be measured between a third battery and a fourth battery (e.g., between the middle of the four-pack and the terminal). The system then estimates the lowest battery voltage (Vₜₑₛₜ) by subtracting the higher voltage divided by two from the lower voltage. For example, if V₁ is greater than V₂, the lowest battery voltage is determined according to Vₜₑₛₜ=V₂−(V₁/2). Conversely, if V₂ is greater than V₁, then the lowest battery voltage is determined according to Vₜₑₛₜ=V₁−(V₂/2). The resultant voltage (Vₜₑₛₜ) is then compared to a threshold voltage (e.g., between 0.85-1.2 volts). If the resultant voltage (Vₜₑₛₜ) is greater than the threshold voltage, then the device is allowed to continue operating. However, if the resultant voltage (Vₜₑₛₜ) is lower than the threshold voltage, the system detects an abnormal battery condition. In response to detecting an abnormal battery condition, a device may cause an indication, such as a light (e.g., LED), to be presented to a user. Additionally or alternatively, the device may stop operation of the device to prevent the battery from deteriorating to leaking and/or corroding the device.

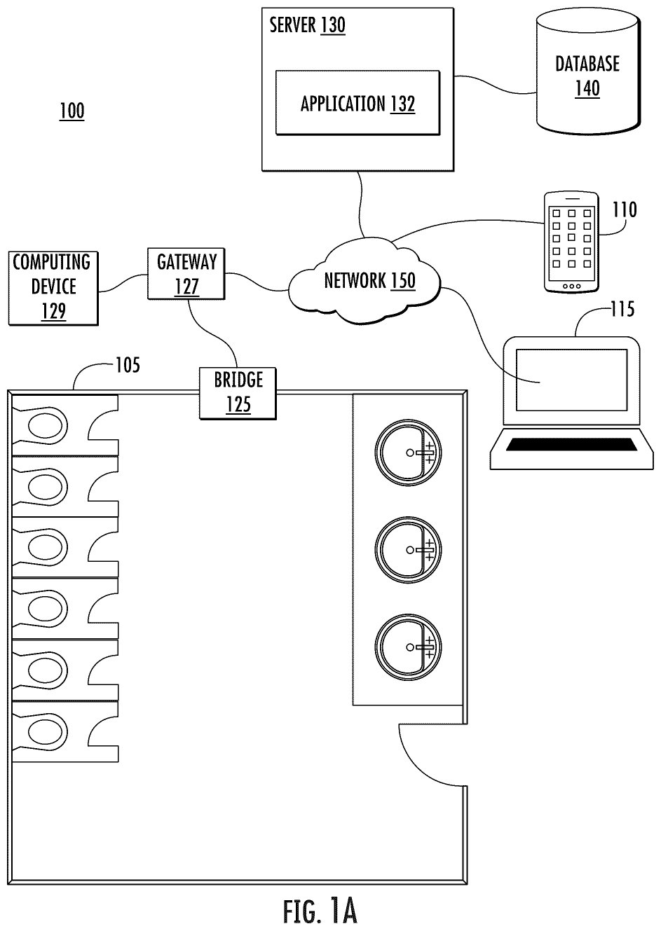

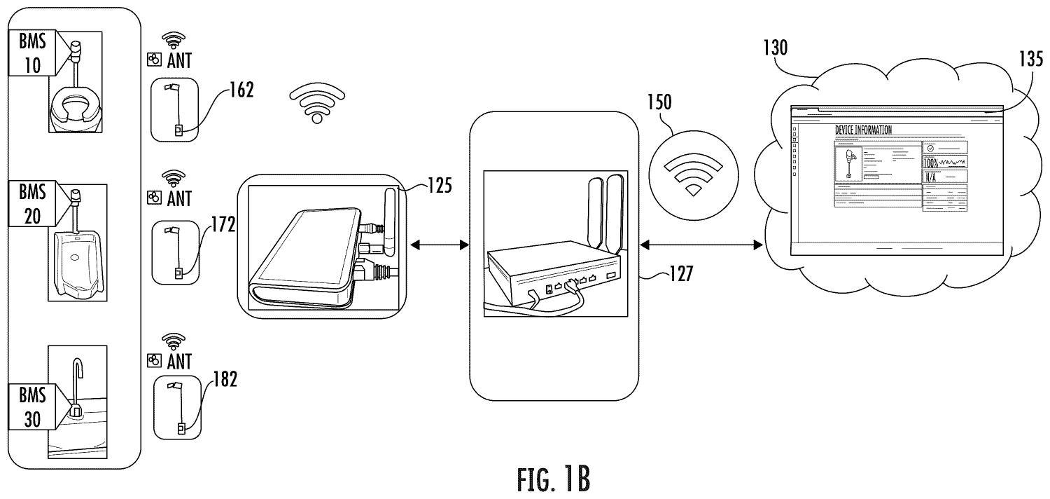

Turning to FIGS. 1A-1B, a connected restroom system 100 according to one or more aspects of the disclosure is shown. The connected restroom system 100 may comprise a restroom 105, a first user device 110, a second user device 115, and a server 130 interconnected via network 150.

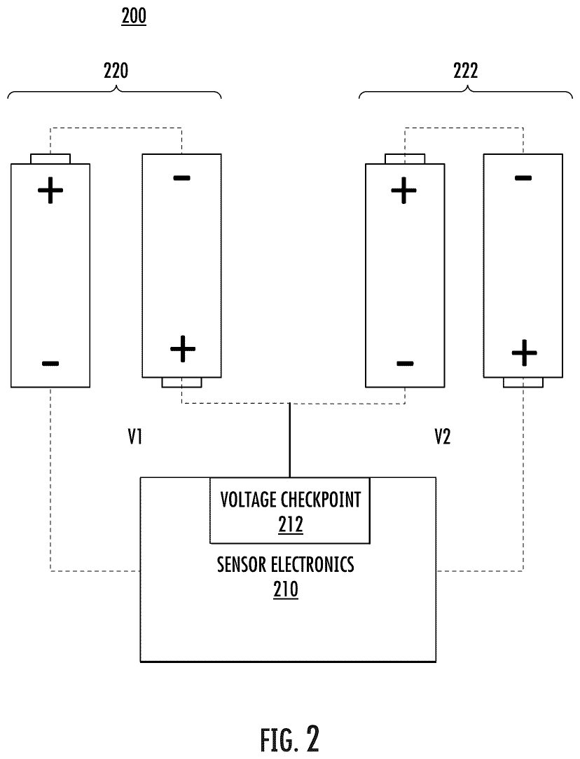

Restroom 105 may be a bathroom in a commercial space, such as an office building, a retailer (e.g., mall), a stadium, etc. The restroom 105 may comprise a plurality of water closets and a plurality of sinks. Although not shown in FIGS. 1A-1B, the restroom 105 may also comprise flushometers attached to toilets and/or urinals, faucets, hand sanitation units, etc. (collectively, “fixtures” or “plumbing fixtures”). Some, if not all, of the fixtures may be battery-operated. Each of the battery-operated fixtures may comprise a battery monitoring system (e.g., 10, 20, 30), which will be discussed in greater detail below with respects to FIGS. 2, 3A-3D, and 4. The battery monitoring systems (e.g., 10, 20, 30) may send battery information to a computing device, such as a local computing device 129 and/or the server 130. The local computing device 129 may be a computing device, such as a server, a user device, a location smart display monitor, or any combination thereof, located on the same premises as the restroom 105. The battery information may be sent to the local computing device 129 via the bridge 125. Additionally or alternatively, the battery information may be sent via bridge 125 and/or gateway 127 to the server 130. In some examples, the battery information may be sent directly to the server 130 via WiFi or cellular networks bypassing, or eliminating, the bridge 125 and/or gateway 127. In response to receiving the signals from the bridge 125, the computing device (e.g., the local computing device 129 and/or the server 130) may display information regarding restroom 105. The information may comprise battery-levels for each of the battery-operated devices. Additionally or alternatively, the information may comprise abnormal battery conditions. For the sake of this disclosure, “abnormal battery conditions” shall include low voltage, leaking batteries, batteries that are discharging too quickly, etc. Additionally, “abnormal battery conditions” shall include the mixing of new and used batteries. By transmitting the battery information to the computing device (e.g., the local computing device 129 and/or the server 130), the computing device (e.g., the local computing device 129 and/or the server 130) may be able to ascertain real-time, or near real-time, battery status and/or operational status with respect to each of the fixtures.

Bridge 125 may be configured to connect one or more fixtures and/or the plurality of battery monitoring systems (e.g., 10, 20, 30) via a network. The network may be a local area network, such as a building or corporate network. The bridge 125 may be a wired or wireless bridge. In preferred embodiments, the bridge 125 comprises a wireless interface to communicate (e.g., send/receive) with one or more fixtures and the plurality of battery monitoring systems (e.g., 10, 20, 30). The wireless interface may use a short-range wireless communication protocol, such as Bluetooth® communications, Bluetooth® Low Energy communications, Wi-Fi communications, ANT communications, LoRa communications, Zig Bee Communications, or any equivalent thereof.

Gateway 127 may be configured to connect the network (e.g., building or corporate network) to a wide area network, such as network 150. The gateway 127 may provide interoperability between building or corporate network and network 150. The gateway 127 may comprise protocol translators, impedance matchers, rate converters, fault isolators, or signal translators. In some examples, the gateway 127 may perform protocol conversions to connect networks with different network protocol technologies.

First user device 110 may be a mobile device, such as a cellular phone, a mobile phone, a smart phone, a tablet, a laptop, or an equivalent thereof. First user device 110 may provide a first user with access to various applications and services. For example, first user device 110 may provide the first user with access to the Internet. Additionally, first user device 110 may provide the first user with one or more applications (“apps”) located thereon. The one or more applications may provide the first user with a plurality of tools and access to a variety of services. In some embodiments, the one or more applications may include an application that provides access to a dashboard, or portal, that provides information about plumbing fixtures and/or battery status. The information may also include information about individual fixtures. The application may comprise an authentication process to verify (e.g., authenticate) the identity of the first user prior to granting access to the dashboard (e.g. portal) 135.

Second user device 115 may be a device configured to allow a user to execute software for a variety of purposes. Second user device 115 may belong to the first user that accesses first user device 110, or, alternatively, second user device 115 may belong to a second user, different from the first user. Second user device 115 may be a desktop computer, laptop computer, or, alternatively, a virtual computer. The software of second user device 115 may include one or more web browsers that provide access to websites on the Internet. These websites may include plumbing websites that allow the user to view information about a building's plumbing, an individual bathroom, and/or an individual fixture. In some embodiments, second user device 115 may include an application that allows the user to access a dashboard 135, or portal, to view information about a building's plumbing, an individual bathroom, and/or an individual fixture. As noted above, the information may comprise battery information. The website and/or the application may comprise an authentication component to verify (e.g., authenticate) the identity of the second user prior to granting access to the dashboard 135 (e.g., portal).

Server 130 may be any server capable of executing application 132. Additionally, server 130 may be communicatively coupled to a database 140. In this regard, server 130 may be a stand-alone server, a corporate server, or a server located in a server farm or cloud-computer environment. According to some examples, server 130 may be a virtual server hosted on hardware capable of supporting a plurality of virtual servers. In some instances, the server 130 may be hosted by a commercial plumbing supply company, such as Sloan Valve Company. The server 130 may be hosted in a cloud provider, such as Microsoft Azure Cloud Service or an equivalent thereof. The server may execute application 132 on behalf of one or more consumers of the products manufactured and distributed by the commercial plumbing supply company.

The application 132 may be server-based software configured to provide users with information about restroom 105. In some embodiments, the application 132 may be server-based software that corresponds to client-based software executing on first user device 110 and/or second user device 115. Additionally, or alternatively, the application 132 may provide users access to the information through a website, or portal, accessed by first user device 110 or second user device 115 via network 150. The application 132 may comprise an authentication module to verify users before granting access to the information. The information may include battery information for each of the battery-operated fixtures. The application 132 may also analyze the information from a plurality of fixtures associated with a location and present the analysis to a user, for example, via the dashboard 135. That is, the application 132 may receive information from each of a plurality of fixtures located in a restroom (e.g., restroom 105). The application 132 may then analyze the information associated with the restroom and present the analysis to a user, via the dashboard 135. The application 132 may provide the analysis with respect to individual restrooms. Additionally or alternatively, the application may provide the analysis for a building, as-a-whole, showing usage and/or statistics for all of the restrooms located in a building. It will be appreciated that the dashboard 135 may allow a user to view usage and/or statistics about the building as-a-whole, while allowing the user to also focus on individual restrooms and/or fixtures. In this regard, the dashboard 135 may provide an overall view of the plumbing of a building, as well as granular data and/or information for individual fixtures. Further, the dashboard 135 may generate notifications, for example, if a fixture has an abnormal battery condition. The notifications may be an electronic communication, such as an email, a text message, a push notification, etc. Additionally or alternatively, the notifications may be displayed via an alert in the dashboard 135 or a smart display monitor.

The database 140 may be configured to store information on behalf of application 132. The information may include, but is not limited to, data about restrooms, such as the quantity, type, model numbers, etc. of the fixtures associated with a restroom. Additionally or alternatively, the information stored in database 140 may comprise battery information of each fixture. User-preferences may also be stored in the database 140. The user-preferences may define how users receive notifications, alerts, etc. The database 140 may include, but is not limited to relational databases, hierarchical databases, distributed databases, in-memory databases, flat file databases, XML databases, NoSQL databases, graph databases, and/or a combination thereof.

Network 150 may include any type of network. In this regard, network 150 may include the Internet, a local area network (LAN), a wide area network (WAN), a wireless telecommunications network, and/or any other communication network or combination thereof. It will be appreciated that the network connections shown are illustrative and any means of establishing a communications link between the computers may be used. The existence of any of various network protocols such as TCP/IP, Ethernet, FTP, HTTP and the like, and of various wireless communication technologies such as GSM, CDMA, WiFi, and LTE, is presumed, and the various computing devices described herein may be configured to communicate using any of these network protocols or technologies. The data transferred to and from various computing devices in system 100 may include secure and sensitive data, such as confidential documents, customer personally identifiable information, and account data. Therefore, it may be desirable to protect transmissions of such data using secure network protocols and encryption, and/or to protect the integrity of the data when stored on the various computing devices. For example, a file-based integration scheme or a service-based integration scheme may be utilized for transmitting data between the various computing devices. Data may be transmitted using various network communication protocols. Secure data transmission protocols and/or encryption may be used in file transfers to protect the integrity of the data, for example, File Transfer Protocol (FTP), Secure File Transfer Protocol (SFTP), and/or Pretty Good Privacy (PGP) encryption. In many embodiments, one or more web services may be implemented within the various computing devices. Web services may be accessed by authorized external devices and users to support input, extraction, and manipulation of data between the various computing devices in the system 100. Web services built to support a personalized display system may be cross-domain and/or cross-platform, and may be built for enterprise use. Data may be transmitted using the Secure Sockets Layer (SSL) or Transport Layer Security (TLS) protocol to provide secure connections between the computing devices. Web services may be implemented using the WS-Security standard, providing for secure SOAP messages using XML encryption. Specialized hardware may be used to provide secure web services. For example, secure network appliances may include built-in features such as hardware-accelerated SSL and HTTPS, WS-Security, and/or firewalls. Such specialized hardware may be installed and configured in system 100 in front of one or more computing devices such that any external devices may communicate directly with the specialized hardware.

FIG. 1B shows an additional perspective of connected restroom system 100. As shown in FIG. 1B, the plurality of battery monitoring systems may be located in plumbing fixtures and/or plumbing hardware. In this regard, a first battery monitoring system 10 may be located in a first flushometer (e.g., Solis Closet), a second battery monitoring system 20 may be located in a second flushometer (e.g., Solis Urinal), and a third battery monitoring system 30 may be located in a faucet (e.g., SW Faucet). It will be appreciated that the battery monitoring systems may be located in a plurality of additional fixtures and/or hardware, including, but not limited to, hand sanitation units, soap dispensers, paper towel dispensers, and/or flood sensors in the floor of a bathroom. Each of the fixtures may comprise a short-range wireless transceiver (e.g., antenna). The short-range wireless transceiver may comprise a SIM card, a micro-SIM card, or an equivalent thereof, embedded in each of the fixtures. As shown in FIG. 1B, the fixture associated with the first battery monitoring system 10 comprises a first transceiver 162, the fixture associated with the second battery monitoring system 20 comprises a second transceiver 172, and the third fixture associated with the third battery monitoring system comprises a third transceiver 182. The short-range wireless transceivers depicted in FIG. 1B may provide one or more of: near field communication (NFC) communications, Bluetooth® communications, Bluetooth® Low Energy communications, Wi-Fi communications, ANT communications, LoRa communications, Zig Bee Communications, or an equivalent thereof.

FIG. 2 shows an example of a battery monitoring system 200 according to one or more aspects of the disclosure. As shown in FIG. 2, the battery monitoring system 200 comprises sensor electronics 210, a voltage checkpoint 212, a first battery pair 220, and a second battery pair 222. First battery pair 220 may comprise two alkaline batteries. Similarly, second battery pair 222 may comprise two alkaline batteries, different from the alkaline batteries of first battery pair 220.

Sensor electronics 210 may be any suitable processor configured to perform the operations described herein. Sensor electronics 210 may include a single central processing unit (CPU), which may be a single-core or multi-core processor, or may include multiple CPUs. Additionally or alternatively, the sensor electronics 210 may include a low-power processor and/or microcontroller, such as an Advanced RISC Machine (ARM) processor, an Atmel 8-bit AVR microcontroller, and/or any suitable field programmable array (FPGA), application specific integrated circuit (ASIC), or system-on-a-chip (SOC). The sensor electronics 210 may execute a series of computer-readable instructions to perform some or all of the processes described herein.

Voltage checkpoint 212 may be any suitable sensor configured to measure the voltage over first battery pair 220 and second battery pair 222. Voltage checkpoint 212 may comprise a first measurement unit configured to measure the voltage over the first battery pair 220 and a second measurement unit configured to measure the voltage over the second battery pair 222. The first measurement unit and/or the second measurement unit may comprise one or more voltmeters. Alternatively, the first measurement unit and the second measurement unit may be configured to measure a first current from the first battery pair 220 and a second current from the second battery pair 222. Using the first current and the second current, a processor (e.g., sensor electronics) may determine (e.g., calculate, derive, etc.) a first voltage from the first current and a second voltage from the second current. The voltage may be determined using Ohm's Law. As will be discussed in greater detail below, the voltages over the first battery pair 220 and the second battery pair 222 may be used to detect (e.g., determine) abnormal battery conditions, such as a low battery, a battery discharging too quickly, or a potential battery leakage.

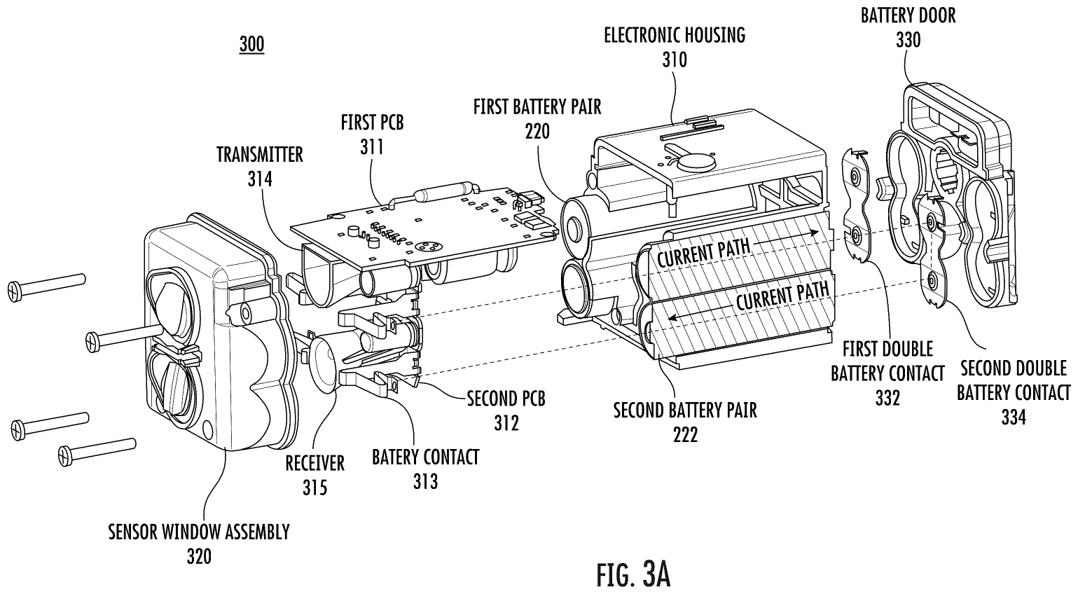

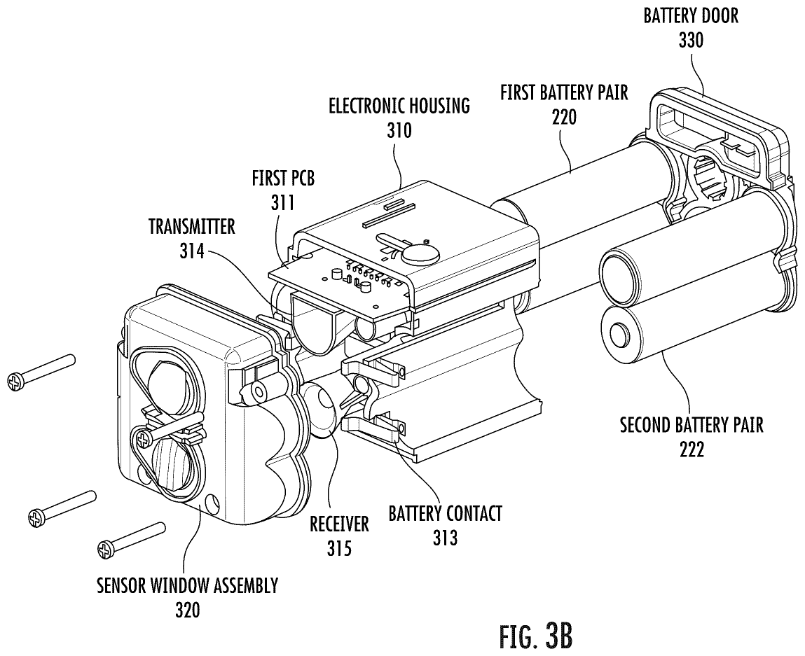

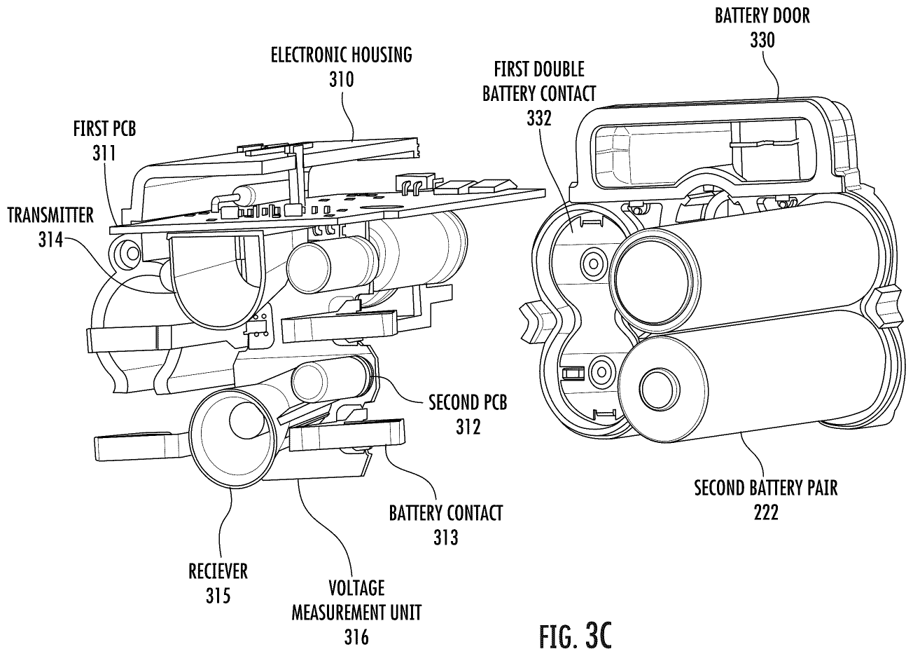

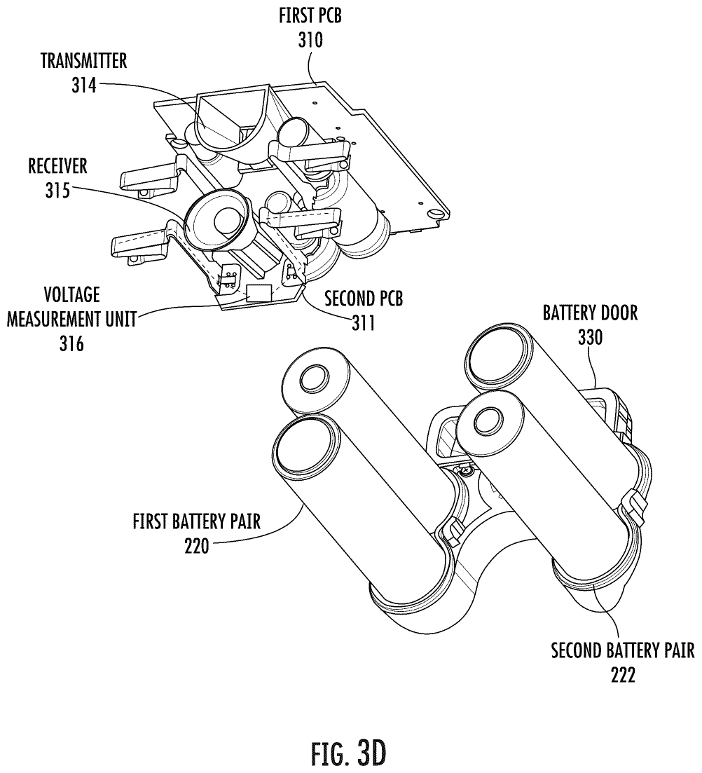

The battery monitoring system shown in FIG. 2 may be deployed in a number of battery-operated devices, including fixtures, such as flushometers attached to toilets and/or urinals, faucets, urinals, hand sanitation units, and the like. FIGS. 3A-3D show various aspects of a battery pack for a flushometer that includes a battery monitoring system in accordance with one or more aspects of the disclosure.

Battery pack 300 comprises an electronic housing 310, a sensor window assembly 320, and a battery door 330. Battery door 330 may comprise a first double battery contact 332 for first battery pair 220 and a second double battery contact 334 for second battery pair 222.

Electronic housing 310 may include a first printed circuit board 311, a second printed circuit board 312. Additionally, electronic housing 310 may comprise a compartment (e.g., opening, void, gap) to receive first battery pair 220 and second battery pair 222. First printed circuit board 311 may comprise one or more processors, memory, and/or circuits (not shown). The one or more processors located on first printed circuit board 311 may be any suitable processor configured to perform the operations described herein. The one or more processors may comprise a single CPU, which may be a single-core or multi-core processor, or may include multiple CPUs. Additionally or alternatively, the one or more processors may include a low-power processor and/or microcontroller, such as an ARM processor, an Atmel 8-bit AVR microcontroller, and/or any suitable FPGA, ASIC, or SOC. The sensor electronics 210 may execute a series of computer-readable instructions to perform some or all of the processes described herein. First printed circuit board 311 may be a motherboard, and second printed circuit board 312 may be a daughterboard attached to first printed circuit board 311.

Second printed circuit board 312 may comprise one or more battery contacts 313. Second printed circuit board 312 may also comprise one or more electronic components. As shown in FIGS. 3A-3D, second printed circuit board 312 comprises a transmitter 314 and a receiver 315. When used together, transmitter 314 and receiver 315 may be configured to detect the presence of an object (e.g., a person) at a fixture. For example, transmitter 314 may emit light in the non-visible spectrum at one or more targets, and receiver 315 may detect non-visible light reflected off the one or more targets (e.g., users). According to some example, transmitter 314 may be configured to emit infrared (IR) light. Receiver 315 may be a photodiode, phototransistor, or the like configured to detect the reflected IR light. Sensor window assembly 320 may comprise a first opening configured to allow signals emitted by transmitter 314 to pass and a second opening configured to allow signals emitted by transmitter 314 and reflected by an object (e.g., person) to be received by receiver 315.

Additionally, second printed circuit board 312 may also comprise voltage measurement unit 316. As noted above, voltage measurement unit 316 may be any suitable sensor configured to measure the voltage of first battery pair 220 and second battery pair 222. Voltage measurement unit 316 may obtain the voltage measurements via one or more battery contacts 313. Voltage measurement unit 316 may comprise a first measurement unit configured to measure a first voltage over the first battery pair 220 and a second measurement unit configured to measure a second voltage over the second battery pair 222. The first measurement unit and/or the second measurement unit may comprise one or more voltmeters. Alternatively, voltage measurement unit 316 may be configured to measure a first current from the first battery pair 220 and a second current from the second battery pair 222 and determine (e.g., calculate, derive, etc.) a first voltage from the first current and a second voltage from the second current. By placing voltage measurement unit 316 on the second printed circuit board 312, the voltage of each battery pair can be measured without having to run wires to battery door 330. By avoiding wires run to battery door 330, batteries may be swapped more easily and without the wires interfering with the installation of the batteries.

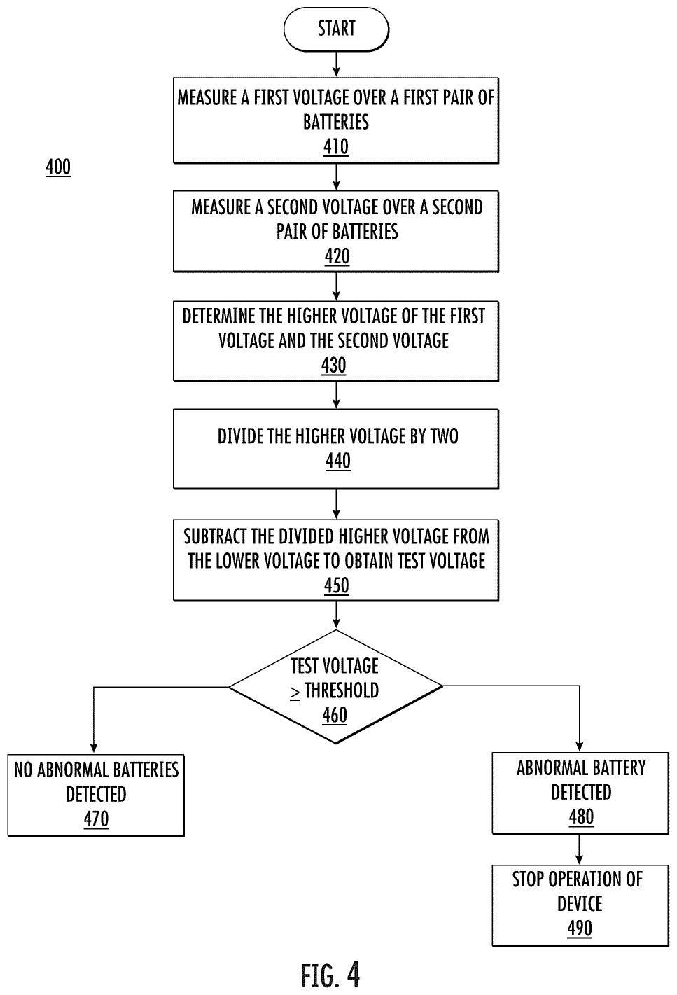

FIG. 4 shows a flow chart of a process 400 for monitoring batteries and detecting abnormal battery conditions. Some or all of the steps of process 300 may be performed using one or more devices described herein, including, for example, battery monitoring system 200 or battery pack 300, or a memory comprising a processor configured to performed the methods described herein.

In step 410, a system (e.g., a battery monitoring system) may measure a first voltage over a first pair of batteries. In step 420, the system may measure a second voltage over a second pair of batteries. The first voltage and the second voltage may be measured, for example, using voltage checkpoint 212 or voltage measurement unit 316 using any of the techniques described above.

After the first voltage and the second voltage are obtained, the system may determine whether the first voltage is greater than the second voltage, in step 430. That is, the system may determine which voltage is higher: the first voltage or the second voltage. In step 440, the system may divide the higher voltage by two. For example, if the first voltage is greater than the second voltage, the system may divide the first voltage by two. If the second voltage is greater than the first voltage, the system may divide the second voltage by two. In step 450, the system may subtract the divided higher voltage from the lower voltage to obtain a test voltage. For example, if the first voltage (V₁) is greater than second voltage (V₂), the lowest battery voltage is determined according to Vₜₑₛₜ=V₂−(V₁/2). Conversely, if the second voltage (V₂) is greater than the first voltage (V₁), then the lowest battery voltage is determined according to Vₜₑₛₜ=V₁−(V₂/2).

In step 460, the system may compare the test voltage to a threshold. That is, the resultant voltage (Vₜₑₛₜ) is then compared to a threshold voltage (e.g., between 0.85-1.2 volts). Typically, the threshold is between 0.85 and 1.2 volts. This threshold may be based on alkaline battery manufacturers' recommendation that alkaline batteries should not operate below 0.8 volts. By setting the threshold between 0.85 and 1.2 volts, the system may shutdown operation of the device before the voltage reaches 0.8 volts, where leaks may occur. This may provide sufficient time to swap out the batteries before a battery leakage occurs.

Additionally or alternatively, the system may compare the resultant voltage (Vₜₑₛₜ) to the average voltage for the battery pack, in step 460. The system may determine the difference between the resultant voltage and the average voltage. The average voltage may be determined by taking the voltage of each battery and dividing by the total number of batteries. In the case of four batteries, the average voltage would be determined by (V₁+V₂+V₃+V₄)/4. If the difference between the resultant voltage and the average voltage is greater than a predetermined difference, the system may determine a discharged or rogue battery is present. As will be discussed in greater detail below, the system may initiate a shutdown based on the determination of the discharged or rogue battery, even if the resultant voltage is greater than the threshold voltage.

In step 470, the system may determine that there is no abnormal battery condition, for example, based on a determination that the test voltage is greater than or equal to the threshold. That is, when the resultant voltage (Vₜₑₛₜ) is greater than the threshold voltage, then the device is allowed to continue operating. However, if the resultant voltage (Vₜₑₛₜ) is lower than the threshold voltage, the system may determine that an abnormal battery condition exists, in step 480.

In step 490, the system may stop (e.g., cease) operation of a device, for example, based on a determination that there is an abnormal battery condition. The device may comprise at least one of: a flushometer, an automatic soap dispenser, an automatic faucet, a paper towel dispenser, or the like. Ceasing operation of the device may prolong the life of the device by preventing a battery from leaking and/or corroding the device. In addition to ceasing operation of the device, the system may cause an indication to be displayed on the device. The indication may comprise one or more indicator lights. The one or more indicator lights may comprise one or more light emitting diodes (LEDs). The one or more indicator lights may indicate a low battery. The one or more indicator lights may allow maintenance, or a facility manager, to address the abnormal battery condition. Additionally or alternatively, the system may send, or transmit, an electronic communication. The electronic communication comprises at least one of a text message, a short messaging service (SMS) message, a multimedia service (MMS) message, an e-mail, a push notification, or an equivalent thereof. The electronic communication may indicate the abnormal battery condition for the device. The electronic communication may be sent prior to the device ceasing operation. The electronic communication may be sent to a server, a user device, or both. The electronic communication may cause an alert, or notification, to be displayed on a dashboard. The dashboard may be accessible (e.g., viewable) via a browser on a user device. Additionally or alternatively, the dashboard may be accessible (e.g., viewable) via an application (e.g., mobile application) on the user device.

While the examples discussed above describe two pairs of batteries, the techniques described herein are equally applicable to more than two battery pairs. In the case of more than two battery pairs, the battery monitoring system may measure the voltage of each pair of batteries (e.g., V₁, V₂, . . . Vₙ, n≥3). To determine the lowest battery voltage, the battery monitoring system described herein would determine the highest voltage and the lowest voltage amongst all the measured voltages. As described above, the battery monitoring system would divide the highest voltage by two and subtract the result of the division from the lowest voltage. The result of the subtraction would then be compared to a threshold using the techniques described above.

Additionally, the techniques described herein may be used to detect abnormal battery conditions when there is an odd number of batteries. In this regard, the last battery (i.e., the odd man out) would be measured separately. If the last battery is greater than the highest voltage divided by two, then the test voltage would be determined by subtracting the voltage of the last battery from the lowest voltage. If the last battery was less than the highest voltage divided by two, then the test voltage would be determined by subtracting the last battery lowest voltage.

While the apparatuses, methods, processes, and techniques described herein disclose monitoring the status of batteries when installed in an end-user product, it will be appreciated that the techniques may be applied to batteries before an end-user product is shipped. That is, batteries may be tested, for example, in a factory before the end-user product is shipped. Batteries may be installed and tested using the processes described above. If the batteries pass testing, the end-user products may be shipped. However, if the batteries do not pass, a quality assurance specialist may be alerted and/or notified of one or more abnormal batteries. This may provide a higher level of quality of assurance with respect to the products being shipped.

It will be appreciated that the apparatuses, methods, processes, and techniques described above may minimize and/or prevent damage to devices by more accurately detecting abnormal battery conditions, including alkaline battery leaks. The techniques described herein may be applied to fresh batteries, newly installed in a device. Additionally, the techniques described herein may be performed periodically (e.g., hourly, daily, weekly, monthly, etc.) to determine the status of the batteries and better ascertain the lifecycle of the batteries.

One or more aspects discussed herein may be embodied in computer-usable or readable data and/or computer-executable instructions, such as in one or more program modules, executed by one or more computers or other devices as described herein. Generally, program modules include routines, programs, objects, components, data structures, and the like. that perform particular tasks or implement particular abstract data types when executed by a processor in a computer or other device. The modules may be written in a source code programming language that is subsequently compiled for execution, or may be written in a scripting language such as (but not limited to) Perl, Python, etc. The computer executable instructions may be stored on a computer readable medium such as a hard disk, optical disk, removable storage media, solid-state memory, RAM, and the like. As will be appreciated by one of skill in the art, the functionality of the program modules may be combined or distributed as desired in various embodiments. In addition, the functionality may be embodied in whole or in part in firmware or hardware equivalents such as integrated circuits, field programmable gate arrays (FPGA), and the like. Particular data structures may be used to more effectively implement one or more aspects discussed herein, and such data structures are contemplated within the scope of computer executable instructions and computer-usable data described herein. Various aspects discussed herein may be embodied as a method, a computing device, a system, and/or a computer program product.

Although certain specific aspects of various example embodiments have been described, many additional modifications and variations would be apparent to those skilled in the art. In particular, any of the various processes described above may be performed in alternative sequences and/or in parallel (on different computing devices) in order to achieve similar results in a manner that is more appropriate to the requirements of a specific application.

Thus, embodiments disclosed should be considered in all respects as examples and not restrictive. Accordingly, the scope of the inventions herein should be determined not by the embodiments illustrated, but by the appended claims and their equivalents.

1. A method for detecting abnormal alkaline battery conditions.

2. The method of claim 1, wherein detecting abnormal batteries further comprises:
measuring a first voltage over a first pair of batteries;
measuring a second voltage over a second pair of batteries;
based on a determination that the first voltage is greater than the second voltage, dividing the first voltage by two;
determining a test voltage by subtracting the divided first voltage from the second voltage; and
compare the test voltage to a threshold.

3. The method of claim 2, further comprising:
determining, based on a determination that the test voltage is greater than or equal to the threshold, that there is no abnormal battery.

4. The method of claim 2, further comprising:
determining, based on a determination that a difference between the test voltage and an average battery voltage is less than the threshold, that there is no abnormal battery

5. The method of claim 2, further comprising:
determining, based on a determination that the test voltage is less the threshold, that there is an abnormal battery; and
stopping, based on a determination that there is an abnormal battery, operation of a device

6. The method of claim 2, further comprising:
determining, based on a difference between the test voltage and an average battery voltage being greater than the threshold, that there is an abnormal battery; and
stopping, based on a determination that there is an abnormal battery, operation of a device.

7. A battery monitoring system comprising:
a first voltage measurement unit configured to measure a first voltage over a first pair of batteries;
a second voltage measurement unit configured to measure a second voltage over a second pair of batteries;
a processor configured to detect an abnormal battery based on the first voltage and based on the second voltage.

8. The battery monitoring system of claim 7, wherein the processor is configured to detect the abnormal battery by:
determining whether the first voltage is greater than the second voltage,
dividing, based on a determination that the first voltage is greater than the second voltage; the first voltage by two;
determining a test voltage by subtracting the divided first voltage from the second voltage; and
compare the test voltage to a threshold.

9. The battery monitoring system of claim 8, wherein the processor is further configured to determine, based on a determination that the test voltage is greater than or equal to the threshold, that there is no abnormal battery condition.

10. The battery monitoring system of claim 8, wherein the processor is further configured to determine, based on a determination that the test voltage is less than the threshold, that there is an abnormal battery condition.

11. The battery monitoring system of claim 10, wherein the processor is further configured to stop, based on a determination that there is an abnormal battery, operation of a device.

12. The battery monitoring system of claim 10, wherein the processor is further configured to stop, based on a determination that there is an abnormal battery, operation of a device.

13. The battery monitoring system of claim 12, wherein the device comprises at least one of:
a flushometer;
an automatic soap dispenser;
an automatic faucet; or
a paper towel dispenser.

14. The battery monitoring system of claim 8, further comprising:
an indicator light configured to indicate a low battery condition based on a determination that the test voltage is less than the threshold.

15. The battery monitoring system of claim 8, further comprising:
a transceiver configured to send an electronic communication indicating a low battery condition.

16. A system comprising:
a plumbing fixture comprising:
a battery monitoring system configured to detect abnormal battery conditions; and
a transceiver configured to transmit or receive one or more electronic communications; and
a server configured to receive one or more electronic communications from the plumbing fixture, wherein the one or more electronic communications indicate an abnormal battery for the plumbing fixture.

17. The system of claim 16, wherein the plumbing fixture comprises at least one of:
a flushometer;
an automatic soap dispenser;
an automatic faucet; or
a paper towel dispenser.

18. The system of claim 16, wherein the server is further configured to cause a dashboard to be displayed on a user device.

19. The system of claim 18, wherein the dashboard indicates the abnormal battery for the plumbing fixture.

20. The system of claim 18, wherein the dashboard is displayed via a mobile application on the user device.

21. The system of claim 18, wherein the dashboard is displayed via a browser on the user device.

22. The system of claim 16, wherein the server is further configured to send a second electronic communication to a user device, wherein the second electronic communication indicates the abnormal battery condition for the plumbing fixture.

23. The system of claim 22, wherein the second electronic communication comprises at least one of:
a text message;
a short messaging service (SMS) message;
a multimedia service (MMS) message;
an e-mail; or
a push notification.
